(19) United States
(12) Patent Application Publication
(10) Pub. No.: US 2009/0191686 A1
(43) Pub. Date: Jul. 30, 2009

(54) Method for Preparing Doped Polysilicon Conductor and Method for Preparing Trench Capacitor Structure Using the Same

(75) Inventors: Chun Yao Wang, Hsinchu (TW); Fu Hsiung Yang, Hsinchu City (TW)

Correspondence Address: WPAT, PC;INTELLECTUAL PROPERTY ATTORNEYS, 2030 MAIN STREET, SUITE 1300, IRVINE, CA, 92614, US

(73) Assignee: PROMOS TECHNOLOGIES INC., Hsinchu (TW)

(21) Appl. No.: 12/108,330

(22) Filed: Apr. 23, 2008

(30) Foreign Application Priority Data
Jan. 29, 2008 (TW) 097103204

(51) Int. Cl. H01L 21/02; H01L 21/3215

(52) U.S. Cl. 438/389; 438/684; 257/E21.011; 257/E21.166; 257/E21.297; 257/E21.316

(57) ABSTRACT

A method for preparing a doped polysilicon conductor according to this aspect of the present invention comprises the steps of (a) placing a substrate in a reaction chamber, (b) performing a deposition process to form a polysilicon layer on the substrate, (c) performing a grain growth process to form a plurality of polysilicon grains on the polysilicon layer, and (d) performing a dopant diffusion process to diffuse conductive dopants into the polysilicon layer via the polysilicon grains to form the doped polysilicon conductor.

### BACKGROUND OF THE INVENTION

(A) Field of the Invention

The present invention relates to a method for preparing doped polysilicon conductors and a method for preparing a trench capacitor structure using the same, and more particularly, to a method for preparing doped polysilicon conductors with reduced resistance and method for preparing a trench capacitor structure with reduced resistance using the same.

(B) Description of the Related Art

A dynamic random access memory (DRAM) memory cell includes an access transistor and a storage capacitor, wherein the source electrode of the access transistor is electrically connected to a top electrode of the storage capacitor and a bottom electrode of the storage capacitor is biased to a positive voltage. Notably, greater electric charges being stored in the storage capacitor relate to reduced occurrence of errors generated from the interpretation of data by a sensing amplifier due to the influence of noise. Therefore, current DRAM memory cells use 3-D capacitors, such as stacked capacitors or trench capacitors, to increase electric charges of the storage capacitor.

FIG. 1 is a cross-sectional view of a trench capacitor structure 10 for DRAM according to the prior art. The trench capacitor structure 10 comprises a substrate 12, two trenches 14 positioned in the substrate 12, a bottom electrode 16 positioned on the outer surface of the trench 14, a dielectric layer 18 positioned on the inner sidewall of the trench 14, and a top electrode 20 positioned on the surface of the dielectric layer 18. The bottom electrode 16, the dielectric layer 18 and the top electrode 20 in each trench 14 form a storage capacitor 30.

In general, the top electrode 20 is formed of polysilicon filling the trench 14 by a deposition process. However, the resistance of the polysilicon is relatively high, and the parasitic capacitance of the polysilicon and the trench capacitor 10 may produce an RC-delay effect, which limits the operating speed of the DRAM.

### SUMMARY OF THE INVENTION

One aspect of the present invention provides a method for preparing doped polysilicon conductors and a method for preparing a trench capacitor structure using the same, which reduces the resistance of the capacitor structure.

A method for preparing a doped polysilicon conductor according to this aspect of the present invention comprises the steps of (a) placing a substrate in a reaction chamber, (b) performing a deposition process to form a polysilicon layer on the substrate, (c) performing grain growth process to form a plurality of polysilicon grains on the polysilicon layer, and (d) performing a dopant diffusion process to diffuse conductive dopants into the polysilicon layer via the polysilicon grains to form the doped polysilicon conductors.

Another aspect of the present invention provides a method for preparing a trench capacitor structure, comprising the steps of (a) placing a substrate in a reaction chamber, the substrate including at least one trench, a bottom electrode positioned on an outer surface of the trench and a dielectric layer positioned on an inner sidewall of the trench, (b) performing a deposition process to form a polysilicon layer on the substrate, (c) performing a grain growth process to form a plurality of polysilicon grains on the polysilicon layer, and (d) performing a dopant diffusion process to diffuse conductive dopants into the polysilicon layer via the polysilicon grains to form a doped polysilicon conductor serving as a top electrode of the trench capacitor structure.

Compared with the prior art, the present invention uses polysilicon grains to increase the diffusion surface for the conductive dopants to increase the amount of the conductive dopants diffused into the polysilicon layer during the subsequent dopant diffusion process, which can further reduce the resistance of the top electrode by increasing the concentration of the conductive dopants therein.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives and advantages of the present invention will become apparent upon reading the following description and upon reference to the accompanying drawings in which:

FIG. 1 is a cross-sectional view of a trench capacitor structure for DRAM according to the prior art; and

FIG. 2 to FIG. 13 illustrate cross-sectional views showing a method for preparing a trench capacitor structure according to one embodiment of the present invention.

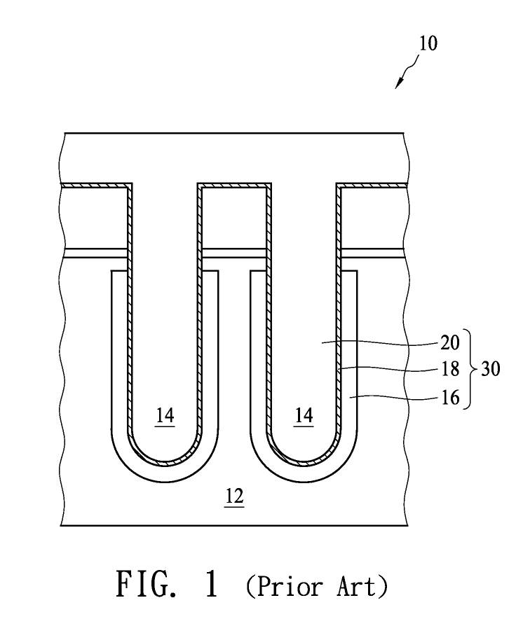

### DETAILED DESCRIPTION OF THE INVENTION

As mentioned in the above paragraphs, the resistance of the polysilicon is relatively high, and the parasitic capacitance of the polysilicon and the trench capacitor and the high resistance of the polysilicon produce an RC-delay effect, which limits the operating speed of the DRAM. To reduce the resistance of the polysilicon, researchers have experimented with a plurality of deposition processes to form several polysilicon layers and a process of introducing a gas containing dopants into the trench at the interval of these deposition processes to diffuse the dopants into the polysilicon layers so as to reduce the resistance of the polysilicon. However, the amount of the dopants diffused into the polysilicon is still limited by the diffusion surface.

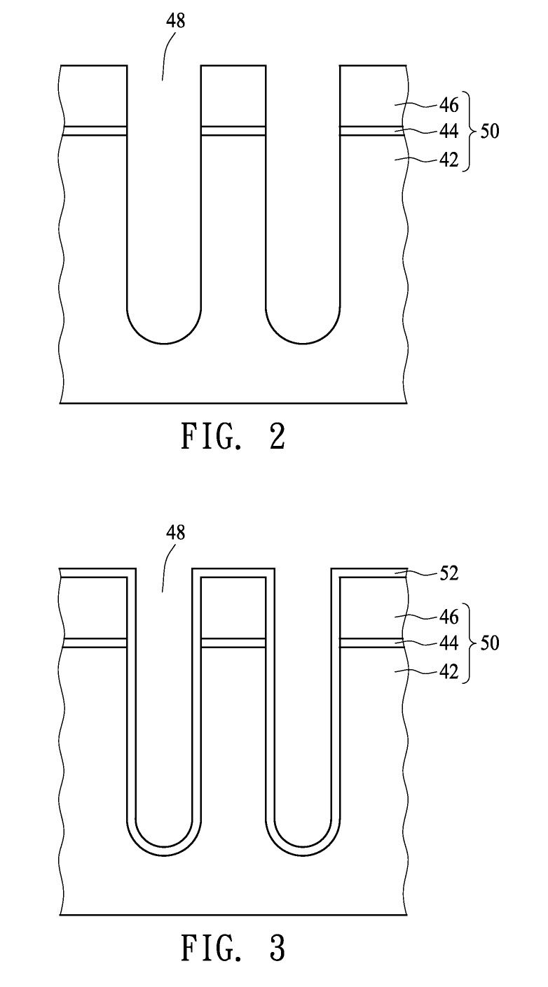

FIG. 2 to FIG. 13 illustrate cross-sectional views showing a method for preparing a trench capacitor structure 40 according to one embodiment of the present invention. First, at least one trench 48 is formed in a substrate 50 including a semiconductor substrate 42 such as a silicon substrate, a silicon oxide layer 44 and a silicon nitride layer 46. Subsequently, a deposition process is performed to form a dielectric layer 52 containing conductive dopants, and the dielectric layer 52 covers an inner sidewall of the trench 48 and the surface of the substrate 50. Preferably, the dielectric layer 52 includes arsenic silicon glass (ASG), and the conductive dopants are arsenic ions.

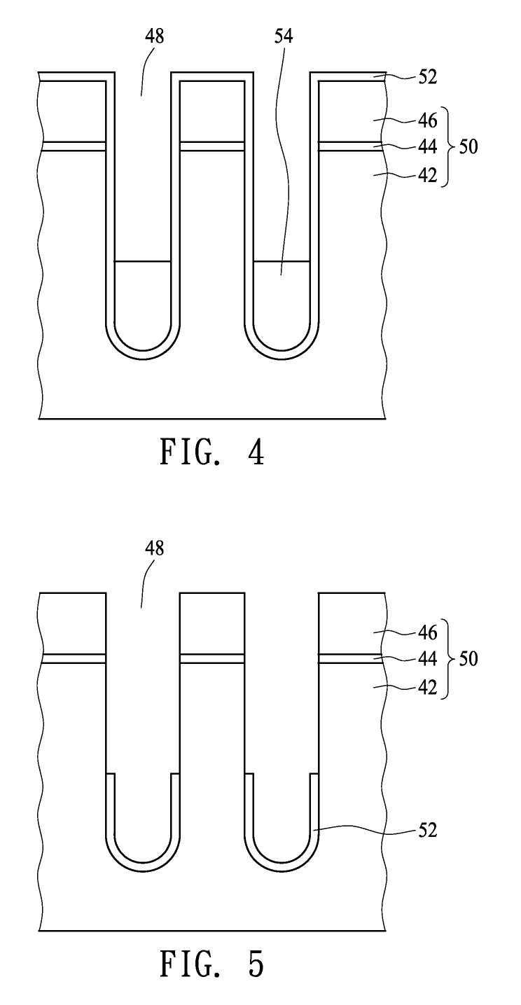

Referring to FIG. 4, a spin-coating process is performed to form a photoresist layer 54 filling the trench 48, and an anisotropic dry etching process is then performed to remove a portion of the photoresist layer 54 above a predetermined depth. Subsequently, the photoresist layer 54 is used as an etching mask 54 and buffered hydrofluoric acid is used as an etchant to perform a wet etching process to remove a portion of the dielectric layer 52 above the photoresist layer 52 such that the remaining dielectric layer 52 covers only a bottom inner sidewall of the trench 48. The photoresist layer 54 remaining in the trench 48 is then removed completely, as shown in FIG. 5.

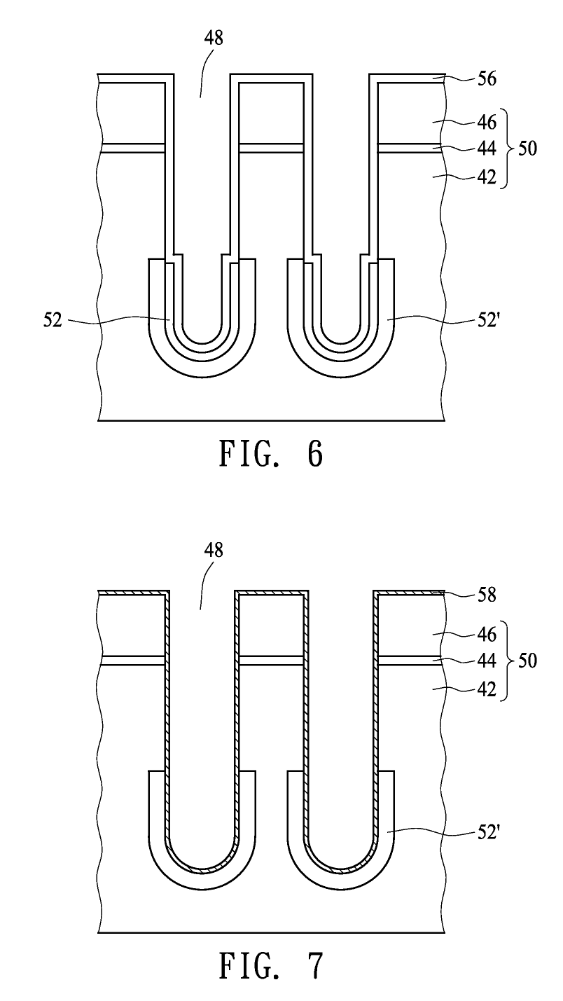

Referring to FIG. 6, a deposition process is performed to form a dielectric layer 56 covering the dielectric layer 52 and the inner sidewall of the trench 48, wherein the dielectric layer 56 can be formed of tetra-ethyl-ortho-silicate (TEOS). A thermal treatment process is then performed to diffuse the dopants of the dielectric layer 52 into the semiconductor substrate 42 on the lower outer surface of the trench 48 so as to form a buried bottom electrode 52′ on the lower outer surface of the trench 48. Subsequently, a wet etching process using buffered hydrofluoric acid as the etchant is performed to remove the dielectric layer 52 and the dielectric layer 56 from the inner sidewall of the trench 48, and another deposition process is performed to form a dielectric layer 58 covering the inner sidewall of the trench 48, as shown in FIG. 7. The dielectric layer 58 can be a laminated dielectric structure of silicon oxide-silicon nitride or a laminated dielectric structure of silicon oxide-silicon nitride-silicon oxide (ONO).

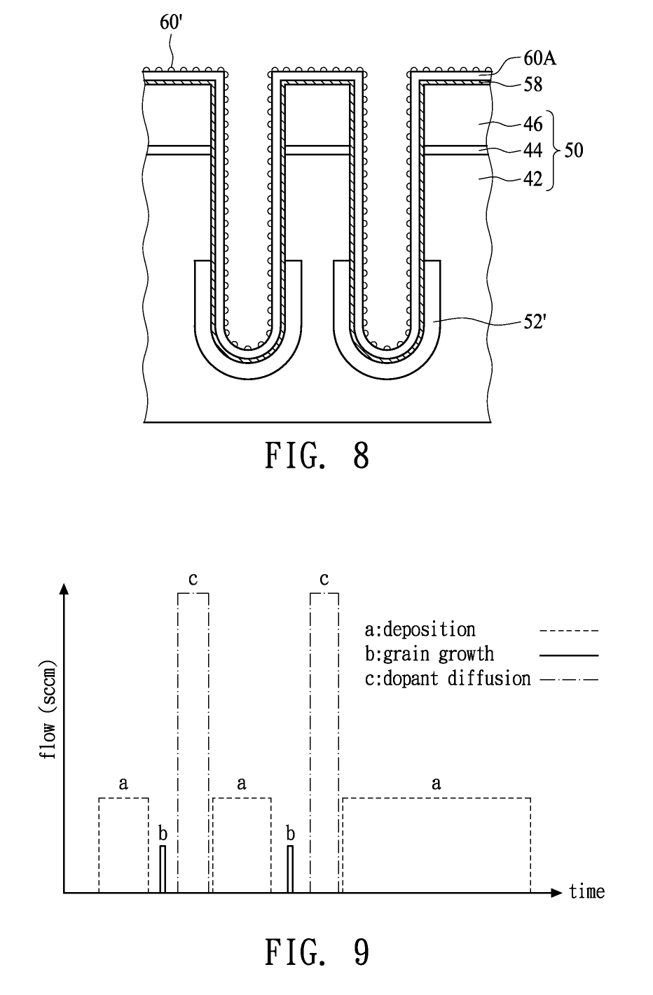

Referring to FIG. 8, the substrate 50 after the above fabrication processes is placed in a reaction chamber to undergo a deposition process to form a polysilicon layer 60A covering the dielectric layer 58, in which a silicon-containing reactant is transferred into the reaction chamber at a first flow of about 300 sccm during the deposition process. A grain growth process is then performed to form a plurality of polysilicon grains 60′ on the polysilicon layer 60A, wherein the silicon-containing reactant is transferred into the reaction chamber at a second flow of between 50 and 150 sccm during the grain growth process; the second flow is smaller than the first flow. Subsequently, a dopant diffusion process is performed to diffuse conductive dopants into the polysilicon layer 60A via the polysilicon grains 60′, in which a gas containing the conductive dopants is transferred at a third flow during the dopant diffusion process.

Referring to FIG. 9 and FIG. 10, the second flow of the grain growth process (b) is smaller than the first flow of the deposition process (a) and the third flow of the dopant diffusion process (c), and the third flow is larger than the first flow. The processing time of the grain growth process (b) is preferably between 1 and 2 minutes, which is shorter than that of the deposition process (a) between 15 and 30 minutes. Preferably, the pressure of the reaction chamber during the deposition process (a) is between 550 and 650 mtorr, and the pressure of the reaction chamber during the grain growth process (b) is between 100 and 200 mtorr, i.e., the pressure of the reaction chamber during the grain growth process (b) is smaller than that during the deposition process (a) and the temperature of the reaction chamber during the grain growth process (b) is preferably between 520 and 580° C. Consequently, the silicon amount transferred into the reaction chamber during the grain growth process (b) is smaller than that transferred during the deposition process (a).

In general, the film formation process can be divided in to five stages: 1. nucleation; 2. grain growth; 3. coalescence; 4. filling of channels; and 5. film growth. According to the present invention, as the silicon transferred into the reaction chamber forms the polysilicon grains 60′ on the polysilicon layer 60A, the grain growth process (b) is substantially stopped by controlling the reaction time, temperature and pressure of the grain growth process (b), and the subsequent coalescence, filling of channels and film growth stages do not occur. In particular, the polysilicon grains 60′ can increase the surface of the polysilicon layer 60A, i.e., increasing the effective diffusion surface, there is an increased diffusion surface for the conductive dopants to diffuse into the polysilicon layer 60A so as to increase the concentration of the conductive dopants in the polysilicon layer 60A and reduce the resistance of the polysilicon layer 60A.

The gas containing conductive dopants can be arsine (AsH₃), and the conductive dopants can be N⁺ type, for example, arsenic ions. The silicon-containing reactant transferred into the reaction chamber during the deposition process (a) and the grain growth process (b) can be the same such as silane (SiH₄). For example, the silicon-containing reactant transferred into the reaction chamber can be silane during the deposition process (a) and silane during the grain growth process (b) while controlling the flow of the silane such that the grain growth process (b) is stopped as the silicon transferred into the reaction chamber forms the polysilicon grains 60′ on the polysilicon layer 60A.

The pressure of the reaction chamber is between 550 and 650 mtorr during the dopant diffusion process (c) and the processing time of the dopant diffusion process (c) is between 20 and 25 minutes. That is, both the pressure and the processing time of the dopant diffusion process (c) are larger than these of the grain growth process (b), which provides another mechanism for increasing the concentration of the conductive dopants in the polysilicon layer 60A. The mechanism is the high pressure of the reaction chamber, i.e., there is a higher concentration of the conductive dopants in the reaction chamber, which can increase the amount of the conductive dopants diffused into the polysilicon layer 60A, which increases the concentration of the conductive dopants in the polysilicon layer 60A and reduces the resistance of the polysilicon layer 60A.

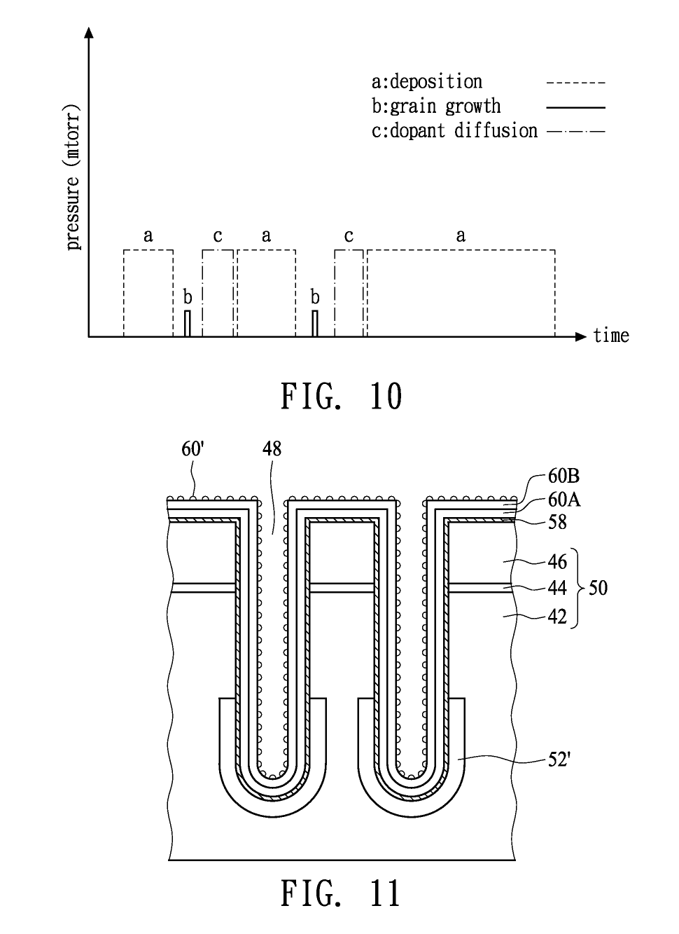

Referring to FIG. 11, the deposition process forming the polysilicon layer 60A is repeated to form a polysilicon layer 60B covering the polysilicon layer 60A, the grain growth process is then repeated to form a plurality of polysilicon grains 60′ on the polysilicon layer 60B, and the dopant diffusion process is repeated to diffuse the conductive dopants into the polysilicon layer 60B via the polysilicon grains 60′ on the polysilicon layer 60B. Subsequently, the deposition process forming the polysilicon layer 60A is performed again to form a polysilicon layer 60C filling the trench 48, as shown in FIG. 12. In particular, the polysilicon layer 60A, the polysilicon layer 60B and the polysilicon layer 60C form a doped polysilicon conductor 64.

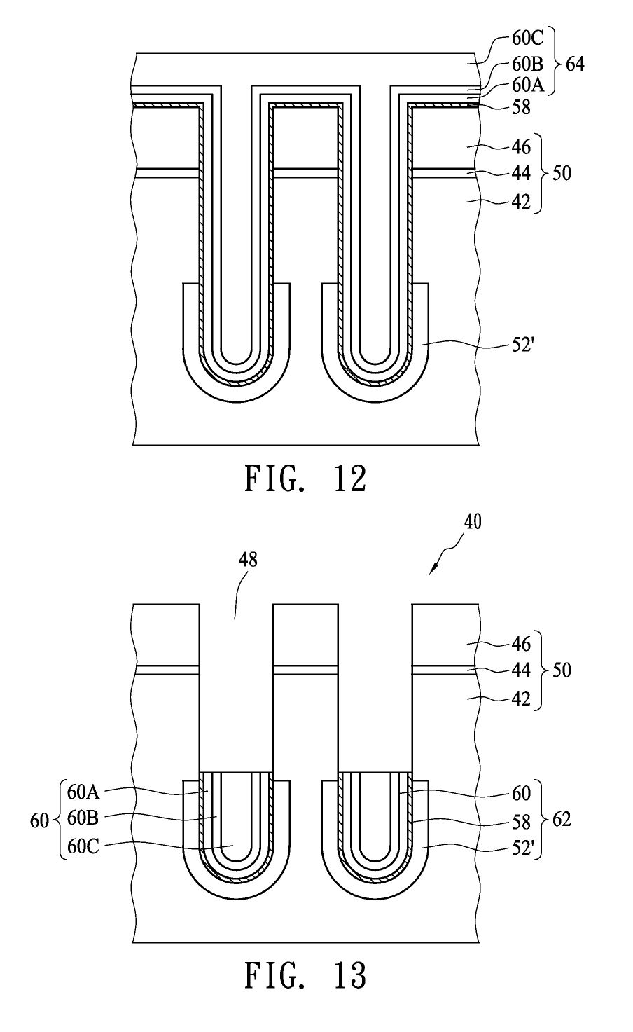

Referring to FIG. 13, an etching process is performed to remove a portion of the doped polysilicon conductor 64 above the substrate 50, and an anisotropic dry etching process is then performed to remove a portion of the doped polysilicon conductor 64 from the trench 48 to form a top electrode 60 filling a lower portion of the trench 48 so as to complete the trench capacitor structure 40. In particular, the buried bottom electrode 52′, the dielectric layer 58 and the top electrode 60 form a capacitor 62 in the lower portion of the trench 48.

In addition to performing a plurality of deposition processes to form the polysilicon layers 60A, 60B and 60C, the present invention also uses the polysilicon grains 60′ to increase the diffusion surface so as to increase the amount of the conductive dopants diffused into the polysilicon layers 60A and 60B during the subsequent dopant diffusion process, which can further reduce the resistance of the top electrode 60 by increasing the concentration of the conductive dopants.

Although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method for preparing a doped polysilicon conductor, comprising the steps of:
(a) placing a substrate in a reaction chamber;
(b) performing a deposition process to form a polysilicon layer on the substrate;
(c) performing grain growth process to form a plurality of polysilicon grains on the polysilicon layer; and
(d) performing a dopant diffusion process to diffuse conductive dopants into the polysilicon layer via the polysilicon grains to form the doped polysilicon conductor.

2. The method for preparing a doped polysilicon conductor of claim 1, wherein the deposition process includes transferring a silicon-containing reactant into the reaction chamber at a first flow, the grain growth process includes transferring the silicon-containing reactant into the reaction chamber at a second flow, and the second flow is smaller than the first flow.

3. The method for preparing a doped polysilicon conductor of claim 1, wherein the deposition process includes transferring a first silicon-containing reactant into the reaction chamber, the grain growth process includes transferring a second silicon-containing reactant into the reaction chamber, and the silicon amount transferred into the reaction chamber during the grain growth process is smaller than that transferred during the deposition process.

4. The method for preparing a doped polysilicon conductor of claim 1, wherein the grain growth process includes transferring a silicon-containing reactant into the reaction chamber at a second flow, the dopant diffusion process includes transferring a gas containing the conductive dopants into the reaction chamber at a third flow, and the third flow is larger than the second flow.

5. The method for preparing a doped polysilicon conductor of claim 1, wherein the processing time of the grain growth process is shorter than that of the deposition process.

6. The method for preparing a doped polysilicon conductor of claim 1, wherein the pressure of the reaction chamber during the grain growth process is smaller than that during the deposition process.

7. The method for preparing a doped polysilicon conductor of claim 1, wherein the silicon amount transferred into the reaction chamber during the grain growth process is smaller than that transferred during the deposition process.

8. The method for preparing a doped polysilicon conductor of claim 1, wherein the temperature of the reaction chamber during the grain growth process is between 520 and 580° C.

9. The method for preparing a doped polysilicon conductor of claim 1, wherein the pressure of the reaction chamber during the grain growth process is between 100 and 200 mtorr.

10. The method for preparing a doped polysilicon conductor of claim 1, further comprising repeating the steps of (b) to (d) for a predetermined number of times.

11. A method for preparing a trench capacitor structure, comprising the steps of:
(a) placing a substrate in a reaction chamber, the substrate including at least one trench, a bottom electrode positioned on an outer surface of the trench and a dielectric layer positioned on an inner sidewall of the trench;
(b) performing a deposition process to form a polysilicon layer on the substrate;
(c) performing grain growth process to form a plurality of polysilicon grains on the polysilicon layer; and
(d) performing a dopant diffusion process to diffuse conductive dopants into the polysilicon layer via the polysilicon grains to form a doped polysilicon conductor serving as a top electrode of the trench capacitor structure.

12. The method for preparing a trench capacitor structure of claim 11, wherein the deposition process includes transferring a silicon-containing reactant into the reaction chamber at a first flow, the grain growth process includes transferring the silicon-containing reactant into the reaction chamber at a second flow, and the second flow is smaller than the first flow.

13. The method for preparing a trench capacitor structure of claim 11, wherein the deposition process includes transferring a first silicon-containing reactant into the reaction chamber, the grain growth process includes transferring a second silicon-containing reactant into the reaction chamber, and the silicon amount transferred into the reaction chamber during the grain growth process is smaller than that transferred during the deposition process.

14. The method for preparing a trench capacitor structure of claim 11, wherein the grain growth process includes transferring a silicon-containing reactant into the reaction chamber at a second flow, the dopant diffusion process includes transferring a gas containing the conductive dopants into the reaction chamber at a third flow, and the third flow is larger than the second flow.

15. The method for preparing a trench capacitor structure of claim 11, wherein the processing time of the grain growth process is shorter than that of the deposition process.

16. The method for preparing a trench capacitor structure of claim 11, wherein the pressure of the reaction chamber during the grain growth process is smaller than that during the deposition process.

17. The method for preparing a trench capacitor structure of claim 11, wherein the silicon amount transferred into the reaction chamber during the grain growth process is smaller than that transferred during the deposition process.

18. The method for preparing a trench capacitor structure of claim 11, wherein the temperature of the reaction chamber during the grain growth process is between 520 and 580° C.

19. The method for preparing a trench capacitor structure of claim 11, wherein the pressure of the reaction chamber during the grain growth process is between 100 and 200 mtorr.

20. The method for preparing a trench capacitor structure of claim 11, further comprising repeating the steps of (b) to (d) for a predetermined number of times.
